(19) United States
(12) Patent Application Publication
(10) Pub. No.: US 2008/0030802 A1
(43) Pub. Date: Feb. 7, 2008

(54) CONTACT IMAGE SENSOR MODULE

(75) Inventors: Chung Che Tsou, Taoyuan County (TW); Shin Ju Lin, Taichung City (TW)

Correspondence Address: WPAT, PC;INTELLECTUAL PROPERTY ATTORNEYS, 2030 MAIN STREET, SUITE 1300, IRVINE, CA, 92614, US

(73) Assignee: RITDISPLAY CORPORATION, Hsin Chu (TW)

(21) Appl. No.: 11/781,802

(22) Filed: Jul. 23, 2007

(30) Foreign Application Priority Data
Aug. 7, 2006 (TW) 095128814

(51) Int. Cl. H01L 27/146

(52) U.S. Cl. 358/482

(57) ABSTRACT

A contact image sensor module for scanning the image of a planar object comprises a white organic electroluminescent device, a plurality of cylindrical lenses, a color filter, and a contact image-sensing element. The white organic electroluminescent device emits white light which illuminates the planar object to result in reflected light. The cylindrical lenses direct the reflected light to the color filter, and the filtered light forms an image in the contact image-sensing element.

### BACKGROUND OF THE INVENTION

1. Field of the Invention

The present invention relates to a contact image sensor module, and more particularly, to an image sensor module for scanning the surface image of a planar object.

2. Description of the Related Art

The image scanner by its basic optical principle can be generally classified into two types—reflected light and transmitted light. The reflected light scanning type works by directing light emitted from a light-emitting diode (LED) array onto the scanned document, and then the light is reflected from the document onto a lens unit. The reflected light is focused through the lens unit to form an image in a charge coupled device (CCD) or a contact image sensor (CIS) module, and corresponding image signals are generated through an encoder comprising a grating wheel.

In comparison with the CCD, the specification of a CIS module has developed from low resolution in the early days to medium-level resolution. Thus, the CIS module has replaced the function of CCD in some product applications. In addition, the CIS module is an integrated module that does not require additional components, such as a lens, a reflector and a motor. Thus it is superior to the CCD in terms of overall cost. Currently the majority of domestic low-price scanners and fax machines use the CIS module as an image signal generator. Manufacturers of such apparatuses also focus their efforts on upgrading related technologies.

The LED array of the CIS module uses a light guide plate to improve the uniformity of light rays. However, the luminance on the light incidence side and the opposing side of the light plate guide tends to be high in terms of the optical principle; hence the quality of image scanning is affected. Moreover, if any of the LED devices of the LED array is damaged, the entire array may be scrapped or repaired such that the maintenance cost is increased. Some manufacturers use a cold cathode fluorescent lamp as the light source for image scanning. But such a device is bigger in size and requires an alternating current source as driving power. Therefore, there are considerable drawbacks in actual application.

FIG. 1 shows a prospective view of a contact image sensor module 10 of prior art as disclosed in ROC Patent No. M240744. An organic light-emitting display device 11 in the contact image sensor module 10 is formed on a glass plate 12 and comprises a plurality of red organic light-emitting diodes 111, green organic light-emitting diodes 112 and blue organic light-emitting diodes 113. The glass plate 12 is fixed on a housing 14. The red organic light-emitting diodes 111, green organic light-emitting diodes 112 and blue organic light-emitting diodes 113 can emit light in sequence, while the red, green and blue lights are reflected by the document on top of the glass plate 12 (not shown in the figure) toward the inside of the housing 14. Then, the reflected light is directed to a contact image-sensing element 16 disposed at the bottom of the housing 14 through a plurality of cylindrical lenses 13. Because the red organic light-emitting diodes 111, green organic light-emitting diodes 112 and blue organic light-emitting diodes 113 are driven and emit light in turns, the speed of scanning is limited to an unsatisfactory maximum level.

In view of the aforesaid drawbacks of the prior art, the optoelectronic market urgently needs a contact image sensor module capable of shortening the scan period, producing uniform light and having a small size.

### SUMMARY OF THE INVENTION

A main objective of the present invention is to provide a contact image sensor module which uses a white light-emitting organic electroluminescent device as the light source for scanning a document image, thereby shortening the scan period, increasing the uniformity of lights and reducing module size.

To achieve the objective, the present invention discloses a contact image sensor module for scanning the image of a planar object, comprising a white organic electroluminescent device, a plurality of lenses (or a lens set comprising a plurality of cylindrical lenses), a color filter, and a contact image-sensing element. The white organic electroluminescent device emits white light which illuminates on the surface of the planar object and reflected light results from the same surface. The cylindrical lenses direct the reflected light to the color filter, and the filtered light forms an image in the contact image-sensing element.

The color filter has band areas that allow respectively red, green and blue light to pass through and are periodically arranged in sequence.

### BRIEF DESCRIPTION OF THE DRAWINGS

The invention will be described according to the appended drawings in which:

FIG. 1 is prospective view of a conventional contact image sensor module;

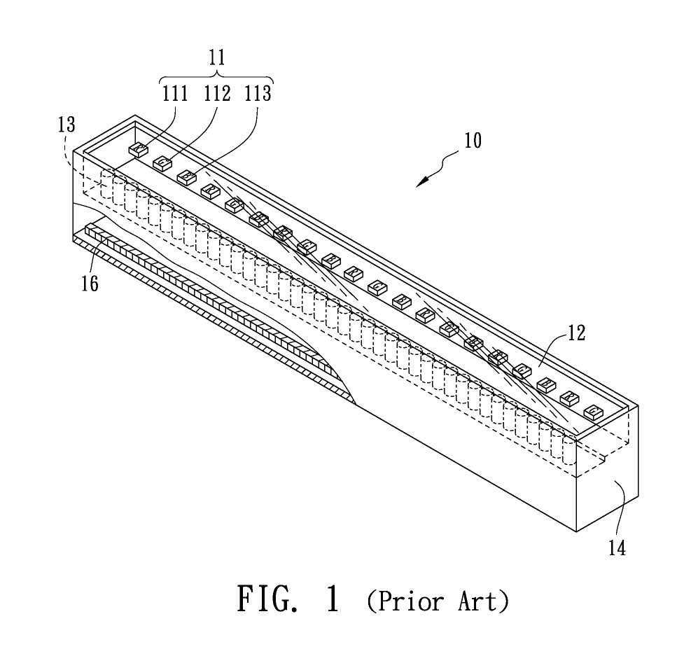

FIG. 2 is an exploded view of a contact image sensor module in accordance with the invention;

FIG. 3 is an assembly view of a contact image sensor module in accordance with the invention; and

FIG. 4 is a cross-sectional view of FIG. 3 taken along section line 1-1.

### PREFERRED EMBODIMENT OF THE PRESENT INVENTION

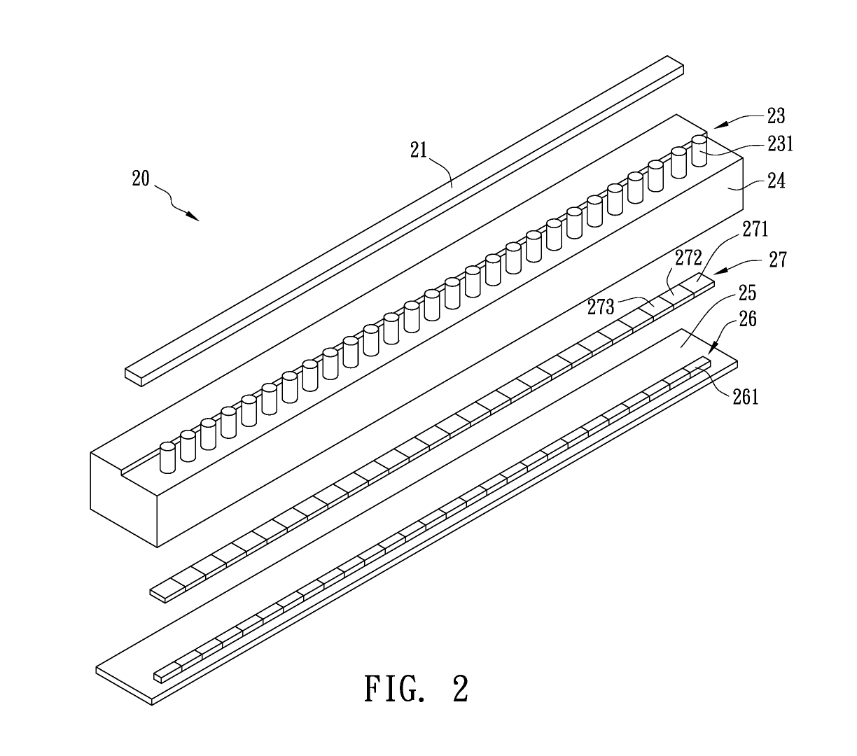

FIG. 2 is an exploded view of a contact image sensor module in accordance with the invention. As shown in FIG. 2, the contact image sensor module 20 comprises a white organic electroluminescent device 21 that emits white light and is fixed at the bottom of a holder 24 and a lens set 23 that comprises a plurality of lenses 231 (e.g. cylindrical lenses) aligned with each other and is also disposed on the holder 24. The lens set 23 can direct the reflected white light toward a color filter 27 disposed at the bottom of the holder 24. The lens set 23 comprising a plurality of lenses 231 can also be substituted by a unitarily-formed optical element.

The band areas 271, 272, and 273 are formed on the color filter 27 in a manner such that they are periodically arranged in sequence, and allow respectively red, green and blue light to pass through. Red, green and blue light passing through the color filter 27 can enter the contact image-sensing element 26 simultaneously, thus shortening the time required to scan a document image as compared to the prior art. The contact image-sensing element 26 is fixed on a printed circuit board 25 and comprises a plurality of contact image sensors 261 arranged along a straight line.

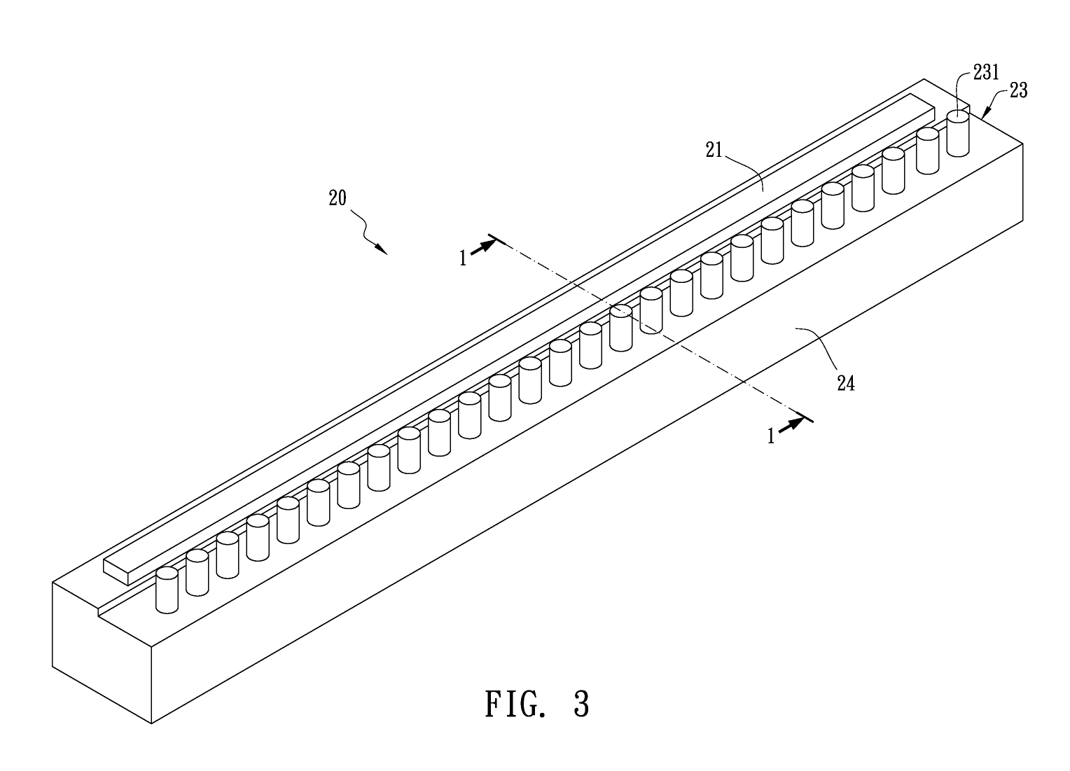

FIG. 3 shows an assembly view of a contact image sensor module in accordance with the invention. As shown in FIG. 3, a room is disposed at the bottom of the holder 24, and encloses the color filter 27, image-sensing element 26, and printed circuit board 25.

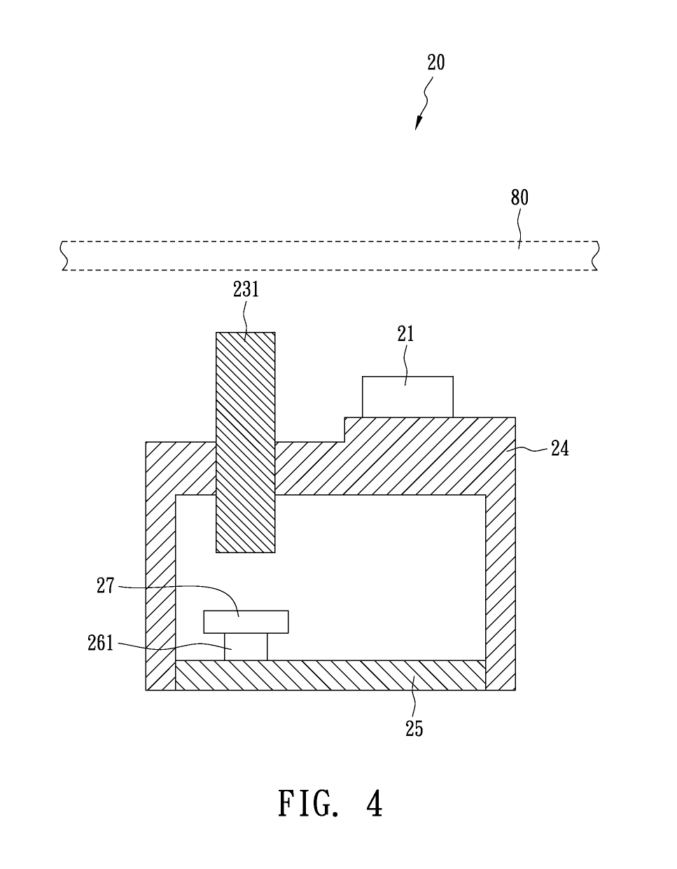

FIG. 4 is a cross-sectional view of FIG. 3 taken along section line 1-1. The white light emitted by the white organic electroluminescent device 21 illuminates the planar object 80 to be scanned, and the surface of the planar object 80 reflects the light to the lens unit 23. The lens unit 23 directs the reflected light toward the color filter 27 and the image-sensing element 26. A linear optical image formed therein is converted into digital image signals by the image-sensing element 26. The printed circuit board 25 that fixes the image-sensing element 26 transmits the digital image signals to the outside of the module.

The above descriptions of the present invention are intended to be illustrative only. Numerous alternative methods may be devised by persons skilled in the art without departing from the scope of the following claims.

What is claimed is:

1. A contact image sensor module for scanning an image of a planar object, comprising:
a white organic electroluminescent device for emitting white light and illuminating the planar object;
a color filter allowing light of specific colors to pass corresponding regions;
a lens set for directing light that is the white light reflected from the planar object to the color filter; and
a contact image-sensing element for sensing light of specific colors that transmit through the color filter and generating image signals.

2. The contact image sensor module according to claim 1, wherein the lens set comprises a plurality of cylindrical lenses aligned with each other.

3. The contact image sensor module according to claim 1, wherein the color filter has band areas that allow respectively red, green and blue light to pass through and are periodically arranged in sequence.

4. The contact image sensor module according to claim 1, wherein the specific colors are red, green and blue.

5. The contact image sensor module according to claim 1, further comprising a holder on which the white organic electroluminescent device and the lens are fixed.

6. The contact image sensor module according to claim 1, further comprising a circuit board on which the contact image-sensing element is fixed.

7. The contact image sensor module according to claim 1, wherein the contact image-sensing element comprises a plurality of contact image sensors aligned with each other.

8. The contact image sensor module according to claim 1, wherein the lens set is a unitarily-formed optical element.
